(19) United States
(12) Patent Application Publication
(10) Pub. No.: US 2013/0193517 A1
(43) Pub. Date: Aug. 1, 2013

(54) SEMICONDUCTOR DEVICE WITH LATERAL AND VERTICAL CHANNEL CONFINEMENT AND METHOD OF FABRICATING THE SAME

(71) Applicant: Akira Hokazono, Clifton Park, NY (US)

(72) Inventor: Akira Hokazono, Clifton Park, NY (US)

(73) Assignee: TOSHIBA AMERICA ELECTRONIC COMPONENTS, INC., Irvine, CA (US)

(21) Appl. No.: 13/362,063

(22) Filed: Jan. 31, 2012

(51) Int. Cl. H01L 27/088; H01L 21/8234

(52) U.S. Cl. 257/368; 438/294; 257/E27.06; 257/E21.618

(57) ABSTRACT

Semiconductor devices and methods of making semiconductor devices are provided. Boron diffusion into source/drain regions is restricted by a vertical and lateral confinement area formed on the surfaces of the source/drain regions. In an aspect, a silicon-carbon layer formed on the surface of the channel region suppresses boron diffusion toward a first source/drain region and toward at least a second source/drain region.

### FIELD

The following description relates generally to methods and systems for fabrication of semiconductor devices comprising lateral and vertical channel confinement.

### BACKGROUND

Silicon large-scale integrated circuits, among other device technologies, are escalating in use in order to accommodate the advanced information society of today and of the future. An integrated circuit may be composed of a plurality of semiconductor devices, such as transistors or the like, which can be produced according to a variety of techniques. To facilitate increased integration and speed of semiconductor devices, a trend of continuously scaling semiconductors (e.g., reducing size and features of semiconductor devices) has emerged.

Reducing semiconductor and/or semiconductor feature size can provide improved speed, performance, density, cost per unit, and so forth, of resultant integrated circuits. However, as semiconductor devices and device features have become smaller, conventional fabrication techniques have been limited in their ability to produce finely defined features.

To improve semiconductor device performance and facilitate device scaling, steep channel profile formation can be utilized. However, a problem associated with steep channel profile formation is the collapse of the steep channel profile. Further, lateral channel dopant diffusion can suppress the semiconductor device characteristic improvements provided by the steep channel profile formation.

### BRIEF DESCRIPTION OF THE DRAWINGS

FIG. 1 illustrates a cross-sectional view of a semiconductor device.

FIG. 2 illustrates a cross-sectional view of the semiconductor device after source/drain regions are recessed.

FIG. 3 illustrates a cross-sectional view of the semiconductor device showing lateral boron diffusion into the source/drain regions.

FIG. 4 illustrates a cross-sectional view of a semiconductor device during a source/drain recess process, according to an aspect.

FIG. 5 illustrates a cross-sectional view of a semiconductor device undergoing a process for confining channel dopant into the source/drain recess portions, wherein the channel dopant is confined laterally and vertically, in accordance with an aspect.

FIG. 6 illustrates alternative views of lateral channel confinement, according to an aspect.

FIG. 7 illustrates a non-limiting example method for lateral vertical channel confinement, according to an aspect.

FIG. 8 illustrates another non-limiting example method for channel confinement, according to an aspect.

### DETAILED DESCRIPTION

The embodiments disclosed herein provide various techniques related to achieving dopant confinement. In an aspect, the channel dopant is confined laterally and vertically. The dopant confinement can be utilized for semiconductor devices that comprise steep channel profiles as well as other semiconductor devices.

As discussed in the background, steep channel profile formation can improve device characteristics. Such steep channel profile formation can be formed by silicon-carbon (Si:C) layers, for example. However, lateral channel dopant diffusion can suppress the advantages of steep channel profile formation. For example, lateral channel dopant diffusion into source/drain regions can cause an undesirable increase in junction capacitance and/or can increase leakage current. Both of which can have a negative influence on device performance and/or can decrease the life expectancy of the device.

The various aspects disclosure herein can be configured to advantageously confine the channel dopant both laterally and vertically. For example, a confinement layer can be placed on the lateral and vertical surfaces of the source/drain regions to mitigate the channel dopant from undesirably diffusing into that area of the device. The dopant confinement systems and methods disclosed herein can improve device performance and/or can increase the lifetime of the device.

An aspect relates to a semiconductor device that can comprise a semiconductor substrate comprising a first transistor region and at least a second transistor region. The first transistor region and the (at least) second transistor region can be isolated by an element isolation region. Further, the semiconductor device can comprise a channel region formed under a first gate electrode, a first source/drain region formed on a first side of the channel region, and a second source/drain region formed on a second side of the channel region. The semiconductor device also comprises a boron doped layer, a silicon-carbon layer formed on the boron doped layer and a surface of the channel region, and a silicon epitaxial channel layer formed on the silicon-carbon layer and the surface of the channel region. A diffusion of the boron doped layer into the channel region is suppressed by the silicon-carbon layer and the silicon epitaxial channel layer formed on the surface of the channel region.

Another aspect relates to a semiconductor device comprising at least one channel region formed under a gate electrode. The semiconductor device also comprises a first source/drain region recessed on a first side of the at least one channel region and a second source/drain region recessed on a second side of the at least one channel region. Further, the semiconductor device comprises silicon-carbon layers formed laterally and vertically around the first source/drain region and the second source/drain region. The semiconductor device also comprises a boron doped layer adjacent the first source/drain region and the second source drain region. A diffusion of the boron doped layer into the first source/drain region and the second source/drain region can be restricted by the silicon-carbon layers formed laterally and vertically within the first source/drain region and the second source/drain region.

Another aspect relates to a method that comprises forming a boron doped layer on a semiconductor substrate, forming a silicon-carbon layer on the boron doped layer, and forming a silicon epitaxial channel layer on the silicon-carbon layer. The method also comprises forming a first channel region under a first gate electrode. Further, the method includes recessing a first source/drain region on a first side of the first channel region and recessing a second source/drain region on a second side of the first channel region. The method also includes epitaxially growing silicon-carbon layers on vertical and lateral surfaces around the first source/drain region and the second source/drain region.

With reference now to the figures, FIGS. 1 to 3 are cross sectional views illustrating various stages a semiconductor can undergo during the formation of a steep channel. It should be noted that the semiconductor can be processed through various stages and, for purposes of simplicity, not all stages are shown and described herein. Instead, the stages shown and described herein are intended to facilitate describing the one or more aspects related to lateral and vertical channel confinement.

Steep channel profile formation by silicon carbon (Si:C) layers can be effective for facilitating device scaling. However, an issue of confined channel dopant diffusing to the source/drain (S/D) regions can develop. This can result in reduced channel concentration, which can degrade device operation at scaled gate length as well as other issues.

FIG. 1 illustrates a cross sectional view of a semiconductor device 100. In an example, the semiconductor device 100 can be an n-type structure, such as a negative-channel metal-oxide semiconductor (nMOS). However, the semiconductor device 100 can be other types of structures.

The semiconductor device 100 is illustrated as having a first transistor region 102, a second transistor region 104, and a third transistor region 106. It should be noted that although three transistor regions are illustrated and described, semiconductor devices can comprise any number of transistor regions and the various aspects disclosed herein are not limited to three transistor regions.

The semiconductor device 100 can contain a semiconductor substrate and a multi-layer structure 108 formed over the semiconductor substrate. The multi-layer structure 108 can contain N layers, where N is an integer, which can be three or more. Although the multi-layer structure 108 can contain three or more layers, for the purpose of brevity, the disclosed aspects will illustrate a multi-layer structure comprising three layers.

In an embodiment, the multi-layer structure comprises a first layer 110 or a lowermost layer over the semiconductor substrate, a second layer 112 or an intermediate layer over the first layer 110, and a third layer 114 or an uppermost layer over the second layer 112. In accordance with some aspects, the first layer 110 can be a layer into which boron (B), as a channel impurity, is doped. The second layer 112 can be a silicon-carbon (Si:C) layer and the third layer 114 can be a silicon epitaxial channel (Si epi) layer, according to an aspect. In an example, the second layer can be an impurity diffusion suppression layer, according to an aspect.

As illustrated, the first transistor region 102 comprises a first gate electrode 116, the second transistor region 104 comprises a second gate electrode 118, and the third transistor region 106 comprises a third gate electrode 120. Gate sidewalls are formed on side faces of the gate electrodes. For example, first gate sidewalls 122 are formed on the side faces of the first gate electrode 116, second gate sidewalls 124 are formed on the side faces of the second gate electrode 118, and third gate sidewalls 126 are formed on the side faces of the third gate electrode 120.

Arrow 128 illustrates that higher channel concentration is needed to reduce depletion layer width under the channel regions. This design can increase junction capacitance (Cj) and/or can increase leakage current (leak), which can degrade device performance and/or reduce a useful life of the device.

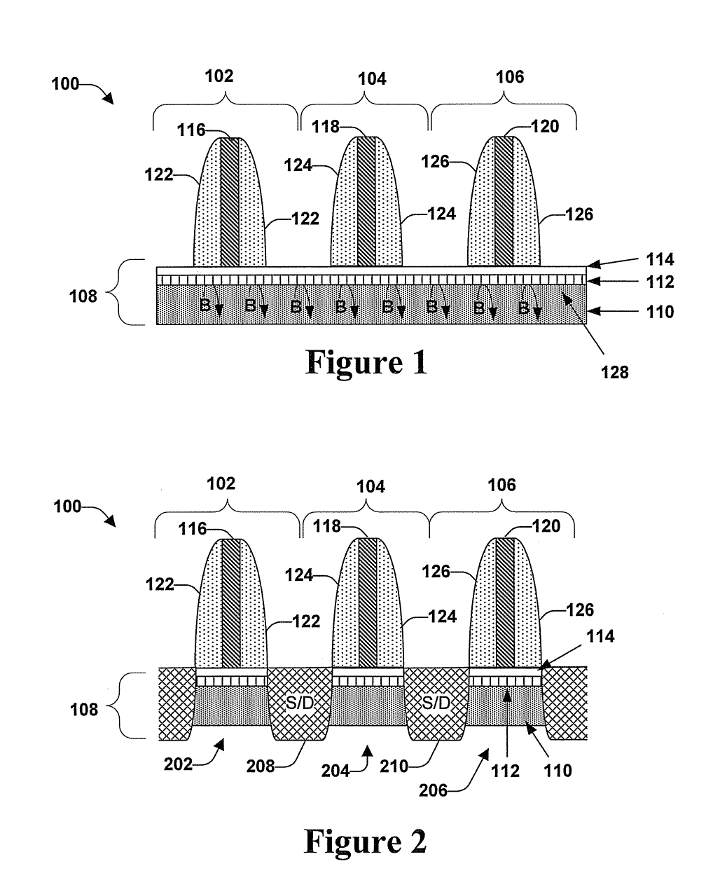

FIG. 2 illustrates channel regions formed in a region of the semiconductor substrate. For example, a first channel region 202 is formed under the first gate electrode 116, a second channel region 204 is formed under the second gate electrode 118, and a third channel region 206 is formed under the third gate electrode 120.

Further, source/drain (S/D) regions are formed on both sides of each of the channel regions. For example, a first S/D region 208 is formed on a first side of the second channel region 204 and a second S/D region 210 is formed on a second side of the second channel region 204. S/D regions are formed on both sides of the other channel regions even though such S/D regions are not illustrated in FIG. 2.

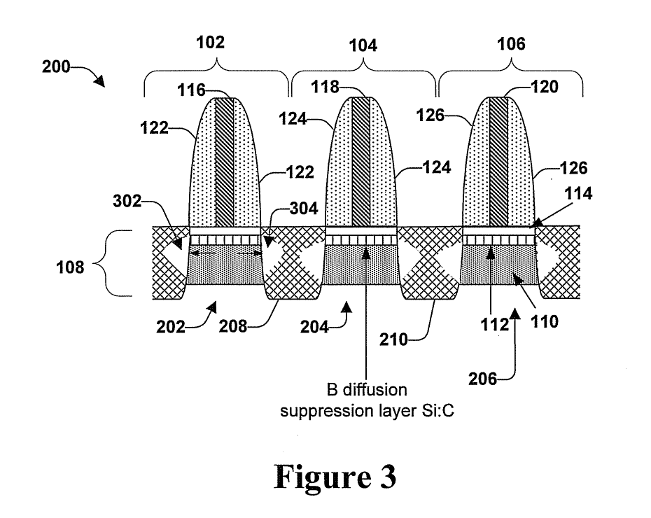

As shown in FIG. 3, in accordance with some aspects, the first layer 110 can be a layer into which boron (B), as a channel impurity, is doped. In an example, the second layer 112 and third layer 114 can be layers into which an impurity is not implemented intentionally. Since diffusion of boron is suppressed in the Si:C layer (e.g., second layer 112 or B diffusion suppression layer (Si:C)), diffusion of boron into the Si layer can be suppressed in a channel region.

As shown in FIG. 3, when anneal is applied during which dopant atom (e.g., boron) can diffuse into positions in the crystal lattice, as illustrated at examples 302 and 304. The diffusion can result in changes (sometimes drastic changes) in the electrical properties of the semiconductor material.

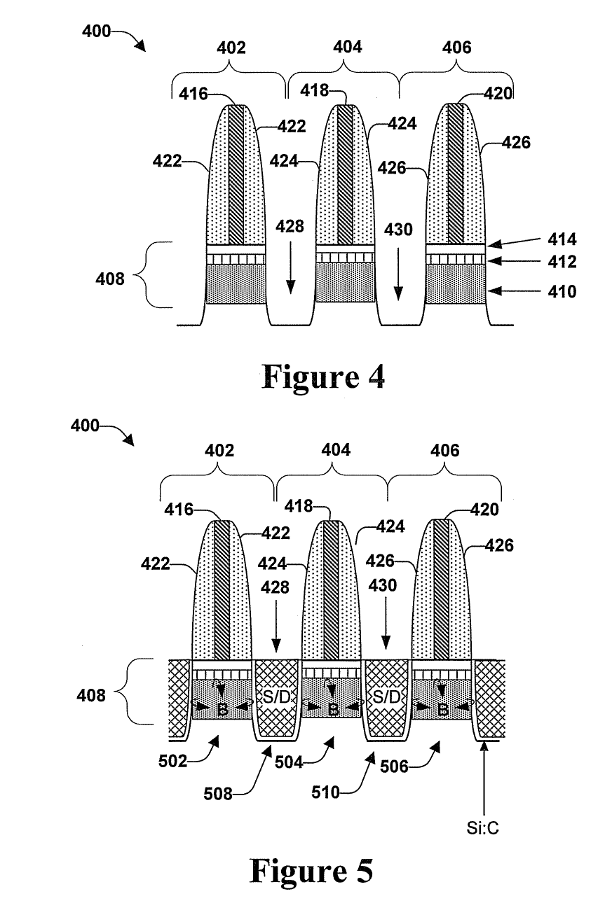

A problem associated with the semiconductor device illustrated in FIGS. 1-3 is that, in the S/D regions 208, 210, there is no recess covered with second layers. That is to say, there is no protective layer between the S/D regions and the channel regions (as will be discussed in further detail in connection with FIGS. 4-8). Since the recesses are not covered (or protected), the boron can diffuse to the S/D regions 208, 210, which can reduce the concentration of boron. Thus, although a channel region having a steep impurity concentration distribution can be formed, the channel concentration can be reduced (e.g., boron is diffused into the S/D regions). This diffusion of the boron into the S/D regions can result in short channel effect (SCE) degradation, which can negatively affect the behavior of devices and/or can negatively impact device performance.

As discussed, to enhance device performance while suppressing short channel effect (SCE), steeper channel profiles can be utilized. Further, as disclosed herein, dopant-diffusion-barriers can be used to suppress unintentional dopant diffusion. As illustrated in FIGS. 1-3, boron diffusion from the bottom doped regions into the channel surface can be suppressed by Si:C layers, where the device design incorporating the bottom doped regions is utilized for device scaling. In accordance with some aspects, additional doping of the bottom doped regions can be utilized to decrease a depletion layer width. For example, if the bottom doped regions are formed without additional implantation, the depletion layer width can become wider, which can cause degradation of SCE and current drive at fixed off-current. Even though there is higher doping concentration in the bottom doped regions in Si:C-Si epi-channel devices, the depletion layer width can be a low value due to the suppression of B-diffusion by the Si:C layer. However, the depletion layer width can become high for a structure that has only a Si-epi channel as a result of the B-diffusion. In accordance with some aspects, if the thickness ratio of the Si:C to epitaxial Si become large, additional implantation for bottom doped regions can be utilized so as not to reduce the effect of SCE control.

FIGS. 4 and 5 illustrate cross-sectional views of a semiconductor device 400 undergoing various stages in the formation of a steep channel, according to an aspect. A semiconductor device 400 can comprise various transistor regions, illustrated as a first transistor region 402, a second transistor region 404, a third transistor region 406, and so forth.

A multi-layer structure 408 is formed over a semiconductor substrate. The multi-layer structure 408 can contain N layers, where N is an integer. Although the multi-layer structure 408 can contain three or more layers, for the purpose of brevity, the disclosed aspects illustrate a multi-layer structure comprising three layers.

In an embodiment, the multi-layer structure comprises a first layer 410 or a lowermost layer over the semiconductor substrate, a second layer 412 or an intermediate layer over the first layer 410, and a third layer 414 or an uppermost layer over the second layer. In accordance with some aspects, the first layer 410 can be a layer into which boron (B), as a channel impurity, is doped. The second layer 412 can be a silicon-carbon (Si:C) layer and the third layer 414 can be a silicon epitaxial channel (Si epi) layer. In an example, the second layer can be an impurity diffusion suppression layer, according to an aspect. Higher channel concentration is needed to reduce depletion layer width under channel regions.

As shown in FIGS. 4 and 5, the first transistor region 402 comprises a first gate electrode 416, the second transistor region 404 comprises a second gate electrode 418, and the third transistor region 406 comprises a third gate electrode 420. Gate sidewalls are formed on side faces of the gate electrodes. For example, first gate sidewalls 422 are formed on the side faces of the first gate electrode 416, second gate sidewalls 424 are formed on the side faces of the second electrode 418, and third gate sidewalls 426 are formed on the side faces of the third gate electrode 420.

As illustrated in FIG. 4, source/drain (S/D) recesses 428, 430 are created. For example, the S/D recesses can be created by recessing one or more layers of the multi-layer structure 408.

FIG. 5 illustrates the Si epi and S/D junction formation or P-doped Si epi. As illustrated, a first channel region 502 is formed in the first transistor region 402, a second channel region 504 is formed in the second transistor region 404, and a third channel region 506 is formed in the third channel region 406.

S/D regions are formed on both sides of channel regions. For example, a first S/D region 508 is formed on a first side of the second channel region 504 and a second S/D region 510 is formed on a second side of the second channel region 504.

As illustrated in FIGS. 4 and 5, a Si:C layer and a Si epi channel layer are formed on the channel surface. For example, the layers can be formed both laterally and vertically on the channel surface.

Further, boron diffusion to the channel surface is suppressed by the Si:C layer and the epi channel layer. For example, Si:C layers are formed at the recessed S/D regions. Thus, as illustrated in FIG. 5, each of the S/D recessed S/D regions 428, 430 has a layer of Si:C formed therein, which acts as a layer or barrier between the S/D and the boron layer. For example, as illustrated in FIG. 5, the Si:C layer is formed laterally and vertically on the surfaces of the S/D regions. Lateral boron diffusion can be retarded by the Si:C layers formed at the recessed S/D regions.

In accordance with some aspects, forming the Si:C layer at the recessed S/D regions can suppress drain induced barrier lowering (DIBL). DIBL is a secondary effect in devices and can refer to a reduction of threshold voltage of the transistor at higher drain voltages. DIBL can also refer to any number of drain-voltage effects upon MOSFET current-voltage (I-V) curves.

According to some aspects, forming the Si:C layer at the recessed S/D regions can reduce junction capacitance (Cj). The junction capacitance is the capacitance associated with the charge variation in the depletion layer. Reduction of the junction capacitance can allow the device (or the circuit) to operate at higher speeds. In accordance with some aspects, reduction of the junction capacitance can allow the device (or the circuit) to operate a lower power for a given speed.

In accordance with some aspects, forming the Si:C layer at the recessed S/D regions can reduce leakage current (leak). For example, leakage current can consume excessive power and can create excessive heat (e.g., overheating a device). Therefore, a reduction in leakage current can increase device performance and/or can increase the life of the device and/or device components.

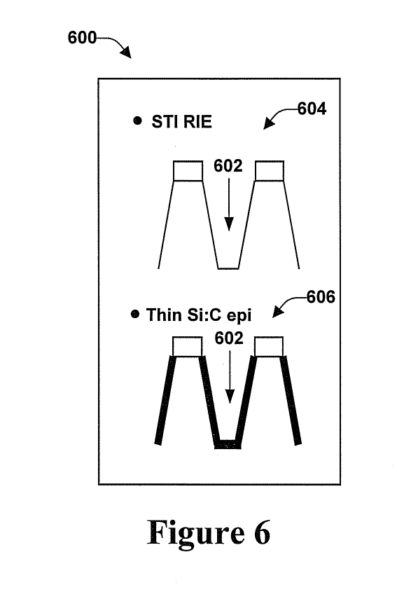

FIG. 6 illustrates alternative views of lateral channel confinement, according to an aspect. In some instances, at a cross point between the gate and the shallow trench isolation (STI), the barrier layer might not formed, or might not be formed completely. Thus, at the edge of the STI, boron can diffuse to the STI region. To address this issue, in addition to the aspects disclosed with reference to FIGS. 4 and 5, a Si:C epi layer is formed after Si recess at STI regions.

In some aspects, carbon doping is applied, then the STI is formed. In various aspects, the boron channel can be corroded by the Si:C layer, which can create a stronger confinement.

As illustrated by the semiconductor device of FIG. 6, shallow trench isolation (STI) can be utilized. STI is a feature that can isolate electrical current leakage between adjacent semiconductor components. STI can be created during early stages or the semiconductor device fabrication. For example, STI can be created before the transistors are formed. Creation of STI includes etching a pattern of trenches. Si:C layer is formed in 602.

Further, one or more dielectric materials are deposited to fill the trenches and excess dielectric is removed. For example, reactive-ion etching (RIE) can be used to form the STI, as illustrated at 604. RIE uses a chemically reactive plasma to remove deposited material. The plasma can be generated under low pressure (e.g., a vacuum) by an electromagnetic field. High-energy ions from the plasma contact the surface and react with the surface.

As illustrated, at 606, a thin Si:C epi can be applied laterally and vertically on surfaces of the recessed area. In some aspects, the Si:C epi can be applied at the side of a S/D region. In various other aspects, the Si:C epi can be formed at the side of a channel region. In an aspect, the Si:C epi can be a thin Si:C epi.

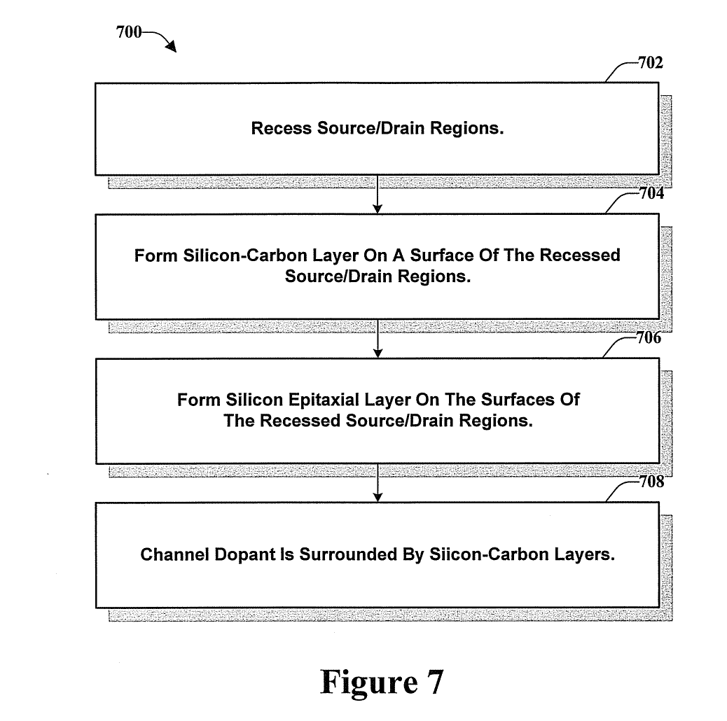

FIG. 7 illustrates a non-limiting example method 700 for lateral vertical channel confinement, according to an aspect. Method 700 is configured to confine channel dopant both laterally and vertically. For example, method 700 can suppress channel dopant diffusion to S/D regions. To suppress the channel dopant diffusion to the S/D regions, Si:C layers can be formed around the S/D regions.

Method 700 starts, at 702, when S/D regions are recessed. The S/D regions can be recessed through one or more layers of a multi-layer structure. According to an aspect, the multi-layer structure can include three or more layers. In accordance with an aspect, the multi-layer structure comprises a B-doped layer, a Si:C layer formed on the B-doped layer, and a Si epi layer formed on the Si:C layer.

At 704, a Si:C (silicon:carbon) epi layer is formed on a surface of the recessed S/D region. Further, a Si epi layer is formed on the surface of the recessed S/D region, at 706. For example, after the S/D regions are recessed, Si:C layers can be epitaxially grown followed by doped epi. The Si:C layer and/or Si epi layer are formed both laterally and vertically on the surface of the recessed S/D regions.

Channel dopant is surrounded by Si:C layers, at 708. This can allow for suppression of lateral dopant diffusion. In such a manner, channel dopant is confined both laterally and vertically, which can facilitate steep channel formation by Si:C layers for device scaling while confining channel dopant diffusion into the S/D regions.

In accordance with some aspects, the Si:C layer formed on the surface of the channel region suppresses boron diffusion toward the channel surface.

According to some aspects, channel dopant is formed by indium. For example, indium can be implanted in the dopant. In accordance with some aspects, the S/D regions are formed by phosphorus doped epitaxial silicon (epi-Si) layers.

In an aspects, lateral boron diffusion is retarded by the Si:C layer and the Si epi layer formed on the surface of the channel region.

In accordance with some aspects, Si:C epi layers are formed at an active region beside a shallow trench isolation (STI) region. According to some aspects, Si:C epi layers are carbon (C) doped at an active region beside a STI region.

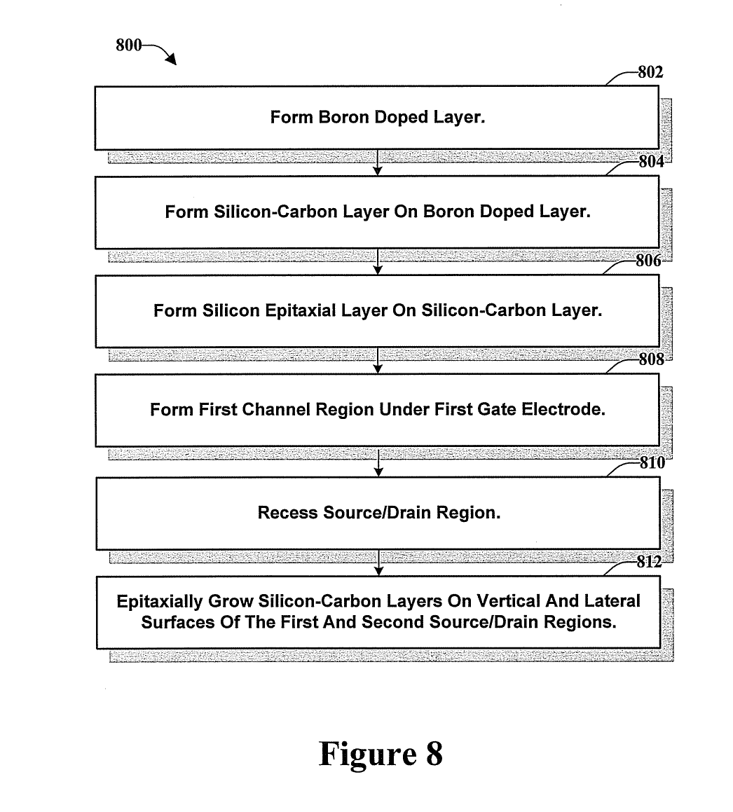

FIG. 8 illustrates another non-limiting example method 800 for channel confinement, according to an aspect. Method 800 starts, at 802, when a boron doped layer is formed on a semiconductor substrate. The boron doped layer can have a first thickness. A silicon-carbon layer is formed on the boron doped layer, at 804. The silicon-carbon layer can have a second thickness. A silicon epitaxial channel layer is formed on the silicon-carbon layer, at 806. The silicon epitaxial channel layer can have a third thickness. In accordance with some aspects, the first thickness, the second thickness, and the third thickness are different thicknesses. According to some aspects, the second thickness and the third thickness are approximately the same thickness.

Method 800 continues, at 808, when a first channel region is formed under a first gate electrode. At 810, a source/drain region is recessed on a side of the channel region. The source/drain region can be recessed through one or more of the silicon epitaxial layer, the silicon-carbon layer, and/or the boron doped layer. In an example, a first source/drain region and a second source/drain region are formed at substantially the same time.

At 812, silicon-carbon layers are epitaxially grown on vertical and lateral surfaces of both the first source/drain region and the second source/drain region (as well as other source/drain regions of the semiconductor device). In accordance with some aspects, epitaxially growing the silicon-carbon layers comprises causing a channel dopant to be confined by the silicon-carbon layers on the vertical and lateral surfaces. Further to this aspect, the channel dopant can be formed by indium.

In accordance with some aspects, epitaxially growing the silicon-carbon layers comprises suppressing lateral dopant diffusion into the source/drain regions.

According to some aspects, recessing the source/drain region can comprise forming the source/drain region with phosphorus doped epi-Si.

In some aspects, method 800 can include forming silicon-carbon epitaxial layers at an active region adjacent a shallow trench isolation region.

As discussed herein, steep channel profile formation by Si:C layers can be effective for device scaling. However, there can be an issue of confined channel dopant diffusion to S/D regions. For example, reduced channel concentration can degrade device operation at scaled gate length. As disclosed herein, to suppress channel dopant diffusion to S/D regions, Si:C layers can be formed around (e.g., vertically and laterally) the S/D regions. The structure can be formed as follows: after S/D regions are recessed, Si:C layers are epitaxially grown followed by doped epi. Channel dopant is surrounded by Si:C layers, and, therefore, lateral dopant diffusion can be suppressed. In this structure, channel dopant is confined laterally and vertically, and therefore dopant confinement can be achieved.

The Si:C layers formed vertically and laterally within the S/D regions can be thought of as a Si:C liner that is formed at the recessed S/D regions. Further, since channel dopant can be confined both laterally and vertically, device performance improvement can be achieved. Further, a life expectancy of the device can be increased.

As provided herein, an aspect relates to a semiconductor device that can comprise a semiconductor substrate comprising a first transistor region and a second transistor region. The first transistor region and the second transistor region can be isolated by an element isolation region. Further, the semiconductor device can comprise a channel region formed under a first gate electrode, a first source/drain (S/D) region formed on a first side of the channel region, and a second S/D region formed on a second side of the channel region. The semiconductor device can also comprise a boron (B) doped layer, a silicon-carbon (Si:C) layer formed on the B doped layer and a surface of the channel region, and a silicon epitaxial channel layer (Si epi) layer formed on the Si:C layer and the surface of the channel region. A diffusion of the B doped layer into the channel region is suppressed by the Si:C layer and the Si epi layer formed on the surface of the channel region.

In an aspect, the Si:C layer formed on the surface of the channel region suppresses boron diffusion channel surface. In some aspects, channel dopant is formed by indium. According to some aspects, the first S/D region and the second S/D region are formed by phosphorus doped epi-Si. In some aspects, lateral boron diffusion is retarded by the Si:C layer formed on the surface of the channel region.

According to some aspects, Si:C epi layers are formed at an active region beside a shallow trench isolation (STI) region. Channel dopant can be formed by indium. Further to this aspect, the first S/D region and the second S/D region are formed by phosphorus doped epi-Si. Further, channel dopant can be formed by indium.

In accordance with some aspects, Si:C epi layers are carbon (C) doped at an active region beside a STI region. Channel dopant can be formed by indium. Further to this aspect, the first S/D region and the second S/D region can be formed by phosphorus doped epi-Si. Further, channel dopant can be formed by indium.

Another aspect disclosed herein relates to a semiconductor device that can comprise at least one channel region formed under a gate electrode. The semiconductor device can also comprise a first source/drain region recessed on a first side of the at least one channel region and a second source/drain region recessed on a second side of the at least one channel region. Further, the semiconductor device can comprise silicon-carbon (Si:C) layers formed laterally and vertically within the first source/drain region and the second source/drain region. The semiconductor device can also comprise a boron doped layer adjacent the first source/drain region and the second source drain region. A diffusion of the boron doped layer into the first source/drain region and the second source/drain region can be restricted by the Si:C layers formed laterally and vertically within the first source/drain region and the second source/drain region.

In accordance with some aspects, the first source/drain region and the second source/drain region are formed by phosphorus doped epi-Si. According to some aspects, the Si:C layers formed laterally and vertically within the first source/drain region and the second source/drain region can be epitaxially grown Si:C layers. In some aspects, the Si:C layers can be formed at an active region beside a shallow trench isolation (STI) region. According to some aspects, Si:C epi layers can be carbon (C) doped at an active region beside a STI region.

Another aspect disclosed herein relates to a method that can comprise forming a boron doped layer on a semiconductor substrate, forming a silicon-carbon layer on the boron doped layer, and forming a silicon epitaxial channel layer on the silicon-carbon layer. The method can also comprise forming a first channel region under a first gate electrode. Further, the method can include recessing a first source/drain region on a first side of the first channel region and recessing a second source/drain region on a second side of the first channel region. The method can also comprise epitaxially growing silicon-carbon layers on vertical and lateral surfaces of the first source/drain region and the second source/drain region.

In an aspect, epitaxially growing the silicon-carbon layers can comprise causing a channel dopant to be confined by the silicon-carbon layers on the vertical and lateral surfaces. In some aspects, the method can further comprise forming the channel dopant with indium.

In accordance with some aspects, epitaxially growing the silicon-carbon layers can comprise suppressing lateral dopant diffusion into the source/drain regions.

According to some aspects, recessing the first source/drain region and the recessing the second source/drain region can comprise forming the first source/drain region and the second source/drain region by phosphorus doped epi-Si.

In some aspects, the method can further comprise forming silicon-carbon epitaxial layers at an active region adjacent a shallow trench isolation region.

With respect to any figure or numerical range for a given characteristic, a figure or a parameter from one range may be combined with another figure or a parameter from a different range for the same characteristic to generate a numerical range. All numbers, values, and/or expressions referring to quantities of ingredients, reaction conditions, etc., used in the specification and claims are to be understood as modified in all instances by the term “about.”

While, for purposes of simplicity of explanation, methods are shown and described as a series of blocks, it is to be understood and appreciated that the disclosed aspects are not limited by the number or order of blocks, as some blocks may occur in different orders and/or at substantially the same time with other blocks from what is depicted and described herein. Moreover, not all illustrated blocks may be required to implement methods described herein.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

What is claimed is:

1. A semiconductor device, comprising:
a semiconductor substrate comprising a first transistor region and a second transistor region, the first transistor region and the second transistor region are isolated by an element isolation region;
a channel region formed under a first gate electrode;
a first source/drain region formed on a first side of the channel region;
a second source/drain region formed on a second side of the channel region;
a boron doped layer;
a silicon-carbon layer formed on the boron doped layer and on a surface of the channel region; and
a silicon epitaxial channel layer formed on the silicon-carbon layer and on the surface of the channel region, wherein diffusion of the boron doped layer into the channel region is suppressed by the silicon-carbon layer and the silicon epitaxial channel layer formed on the surface of the channel region and wherein the silicon-carbon layer formed on the surface of the channel region suppresses boron diffusion toward the first source/drain region and the second source/drain region.

2. The semiconductor device of claim 1, wherein channel dopant comprises indium.

3. The semiconductor device of claim 1, wherein the first source/drain region and the second source/drain region comprise phosphorus doped epitaxial silicon.

4. The semiconductor device of claim 1, wherein lateral boron diffusion is retarded by the silicon-carbon layer and the silicon epitaxial channel layer formed on the surface of the channel region.

5. The semiconductor device of claim 1, wherein silicon-carbon epitaxial layers are formed at an active region beside a shallow trench isolation region.

6. The semiconductor device of claim 5, wherein channel dopant comprises indium.

7. The semiconductor device of claim 5, wherein the first source/drain region and the second source/drain region comprise phosphorus doped epitaxial silicon.

8. The semiconductor device of claim 7, wherein channel dopant comprises indium.

9. The semiconductor device of claim 1, wherein silicon-carbon epitaxial layers are carbon doped at an active region beside a shallow trench isolation region.

10. The semiconductor device of claim 9, wherein channel dopant comprises indium.

11. The semiconductor device of claim 9, wherein the first source/drain region and the second source/drain region comprise phosphorus doped epitaxial silicon.

12. The semiconductor device of claim 9, wherein the channel dopant comprises indium.

13. A semiconductor device, comprising:
at least one channel region formed under a gate electrode;
a first source/drain region recessed on a first side of the at least one channel region;
a second source/drain region recessed on a second side of the at least one channel region;
silicon-carbon layers formed laterally and vertically within the first source/drain region and the second source/drain region;
a boron doped layer adjacent the first source/drain region and the second source/drain region, wherein diffusion of the boron doped layer into the first source/drain region and the second source/drain region is restricted by the silicon-carbon layers formed laterally and vertically within the first source/drain region and the second source/drain region.

14. The semiconductor device of claim 13, wherein the first source/drain region and the second source/drain region comprise phosphorus doped epitaxial silicon.

15. The semiconductor device of claim 13, wherein the silicon-carbon layers formed laterally and vertically within the first source/drain region and the second source/drain region are epitaxially grown silicon-carbon layers.

16. The semiconductor device of claim 13, wherein the silicon-carbon layers are formed at an active region beside a shallow trench isolation region.

17. The semiconductor device of claim 13, wherein silicon-carbon epitaxial layers are carbon doped at an active region beside a shallow trench isolation region.

18. A method of processing a semiconductor structure, comprising:
forming a boron doped layer on a semiconductor substrate;
forming a silicon-carbon layer on the boron doped layer;
forming a silicon epitaxial channel layer on the silicon-carbon layer;
forming a first channel region under a first gate electrode;
recessing a first source/drain region on a first side of the first channel region;
recessing a second source/drain region on a second side of the first channel region; and
epitaxially growing silicon-carbon layers on vertical and lateral surfaces of the first source/drain region and the second source/drain region.

19. The method of claim 18, wherein epitaxially growing the silicon-carbon layers comprises causing a channel dopant to be confined by the silicon-carbon layers on the vertical and lateral surfaces.

20. The method of claim 19, further comprising forming the channel dopant with indium.
